(19) United States
(12) Patent Application Publication
(10) Pub. No.: US 2004/0072450 A1
(43) Pub. Date: Apr. 15, 2004

(54) Spin-coating methods and apparatuses for spin-coating, including pressure sensor

(76) Inventors: Jimmy D. Collins, Allen, TX (US); Samuel A. Cooper, Plano, TX (US)

Correspondence Address: KAGAN BINDER, PLLC, Maple Island Building, Suite 200, 221 Main Street North, Stillwater, MN, 55082, US

(21) Appl. No.: 10/271,525

(22) Filed: Oct. 15, 2002

(51) Int. Cl. H01L 21/31; H01L 21/469; H01L 21/00

(52) U.S. Cl. 438/782; 438/5

(57) ABSTRACT

Described are methods and apparatuses useful for spin-coating process solutions onto substrates, wherein the methods and apparatuses incorporate a pressure sensor to detect the pressure of a process solution, such as a pressure related to a beginning or end of a dispense of process solution from a dispenser; some preferred methods and apparatuses measure pressure of a photoresist, developer, water, solvent, or cleaner in a dispense line; and some preferred methods and apparatuses incorporate process control systems involving interrupted, parallel control methods.

### FIELD OF THE INVENTION

The invention relates to spin-coating methods and apparatuses, including control systems, for applying materials such as process solutions onto substrates such as wafers for semiconductor devices and other microelectronic devices. The methods and apparatuses incorporate a pressure sensor that can be used to monitor and control steps of spin-coating processes, and to detect malfunctions.

### BACKGROUND

Certain manufacturing processes call for coating thin films of materials onto various commercially important substrates. One method that has been used commercially for applying materials onto a substrate is spin processing or spin-coating, using a spin-coater. A spin-coater allows placement of a quantity of a material onto a substrate, and can rotate the substrate about its central axis through one or a series of rotational speeds. Centrifugal action causes the material to spread out over the surface of the spinning substrate, e.g., into a thin, uniform film.

More generally, processing of various commercially important substrates, e.g., semiconductor wafers containing microelectronic devices and integrated circuits, requires that some process steps be limited to well-defined areas of the surface of a substrate. This is true, for example, in processing microelectronic devices, to precisely place different materials onto a semiconductor wafer to construct circuit designs. A step of such a process is to precisely delimit the different areas of the substrate that must be either processed or protected from the actions of processing materials and processing steps. Common methods of processing such substrates include photolithography and spin-coating.

Photolithography is used to selectively protect or expose areas of a substrate such as a microelectronic device. A coating of a photosensitive photoresist material is spin-coated as a thin layer onto the device. Other process solutions such as solvents can optionally be applied to the substrate (coated) as well. The photoresist layer is exposed to electromagnetic energy through a patterned photomask, causing a chemical reaction of the exposed photoresist material, but not of the materials of the masked area (i.e., not exposed to electromagnetic energy). Afterward, a developer solution is spin-coated or otherwise applied to the entire photoresist material. The developer solution causes either the exposed or unexposed areas of the photoresist to be “developed,” which allows removal of the developed or undeveloped photoresist. If the photoresist is of a so-called negative type, the unexposed area of the coating can be developed and removed; if the photoresist is of a so-called positive type, the exposed regions of the photoresist coating can be developed and removed. In both types of photolithography, the remaining photoresist forms a protective layer in either a positive or a negative pattern of the photomask that allows further processing of the exposed areas while protecting the areas covered by the photoresist.

The thickness of the photoresist layer (just prior to exposure) can have significant effects on one or more of the quality, performance, and cost of manufacture of the end product microelectronic device. The thickness of the exposed and developed photoresist layer can affect the size and resolution of features that can be constructed on the substrate using the photoresist layer. A thinner photoresist layer will allow finer features and finer resolution of features based on a range of useful aspect ratios (i.e., height versus width) of the features. Additionally, when using monochromatic light to expose a photoresist layer, the light can pass through the layer and be reflected, thereby causing either constructive or destructive interference. A desired film thickness can be designed to operate at either a maxima or minima of the thin film interference/swing curve.

To produce small features in a uniform fashion, the uniformity of the photoresist layer is also important, meaning both the uniformity of the thickness of a photoresist film on a single substrate (the “intra-wafer uniformity”) and the uniformity of the (average) thickness between different coatings applied to different substrates (the “inter-wafer uniformity”). The intra-wafer uniformity is important, e.g., because it provides uniformity of the feature sizes of components placed on any given device. Inter-wafer uniformity is important, e.g., because producing coatings having predictably uniform thickness allows the production of devices having uniform and consistent quality.

As explained, the developed photoresist layer is a product of a multi-step process including coating a photoresist solution and coating a developer solution (after exposing the photoresist). Both of the process steps and their related materials can be key in producing a developed photoresist layer with uniform and predictable thicknesses, and with uniform feature sizes.

Spin-coating methods attempt to provide coating uniformity by closely monitoring or controlling process conditions, materials, and individual process commands, to cause execution of spin-coating process steps in a uniform, repeatable fashion. This is generally accomplished by programming a computerized process control system to cause uniform execution of individual process steps with repetitive, predicted, timing and conditions, according to a pre-programmed set of events. Moreover, due to the very small dimensions and tolerances involved, factors surrounding the process that might otherwise be considered insignificant can have frustratingly real consequences in causing very small variability and non-uniformity of spin-coated materials. Examples of such factors can include the viscosity and temperature of a process solution, spin speed and acceleration, process timing delays, air movement and velocity in the coating apparatus, ambient humidity, ambient temperature, ambient barometric pressure, chemical dispense system parameters, small variations in timing, mechanical impingement of applied process solutions, etc. Certain methods exist to monitor and compensate for some of these factors to reduce their effects on the thickness of spin-coated materials.

Spin-coating processes typically account for and control processing conditions using a computerized process control system. One system often used for controlling spin-coating processes involves serial process control, e.g., a “round-robin”-type control process. In a serial-type control process, an electronic or computerized unit monitors and controls various elements of a spin-coating system using a sequential or serial methodology. The process control system operates generally according to a continuous, serial (e.g., circular) path, sequentially addressing pre-identified components of the apparatus in a pre-determined order that does not vary (see FIG. 3). In practice, a computer or central processing unit (CPU) can be programmed to sequentially address one subroutine at a time. In FIG. 3, subroutines are represented by the rays emanating from the path followed by the CPU. The CPU addresses a subroutine, performs the instructions of the subroutine by checking conditions or parameters and taking any instructed action, and after any such action is taken, moving to the next subroutine. FIG. 3 shows numerous rays that represent subroutines. Some rays are labeled to identify exemplary subroutines and some are not.

Limits remain on coating uniformity attainable by spin-coating using known process control methods and known techniques for monitoring, controlling, or compensating for internal and external processing conditions and equipment variations. This is especially true as feature sizes of microelectronic devices become smaller and tolerances for variation in feature size become more demanding. New, better, and more precise ways of measuring, timing, and controlling spin-coating processes are still needed.

### SUMMARY OF THE INVENTION

The invention relates to spin-coating systems, e.g., apparatuses, which contain a pressure sensor for measuring pressure of a process solution. The process solution may be any of a variety of process solutions used in microelectronics processing, such as solvents (including water as organic solvents), cleaners, photoresist, developer, etc. The pressure sensor can be incorporated into spin-coating systems and methodologies, as described herein, either alone or preferably in combination with selected process control systems, to improve control of spin-coating systems and spin-coating processes, or to monitor proper functioning of a spin-coating system by noticing irregularities or other malfunctions.

The pressure sensor can be used, for example, for providing information related to the pressure of a process solution in a dispense line at a time related to a dispense step. This information can allow the detection and monitoring of the overall dispense process, including monitoring the beginning or the end of dispense of process solution based on the pressure measured by the pressure sensor. Other useful information (other than beginning or end of a dispense) can also be derived from the same pressure signal, such as from the value of the pressure reading at a particular repeated point in a dispense step. Such information may be useful to detect a slow drift or an abrupt change in an amount of pressure within a dispense line at a repeating point in a dispense process, e.g., a point during or slightly before or after a dispense step. This may indicate a slow or abrupt irregularity or malfunction in the spin-coating system such as a minor or major line clog, a minor or major leak, or any other type of minor or major equipment malfunction.

The invention also relates to spin-coating processes and process control systems that incorporate such a pressure sensor.

Certain preferred embodiments of the invention relate to apparatuses and methods wherein spin-coating is controlled using a computerized process control system, especially a “parallel” process control system that interrupts serial process control to execute process commands in parallel, thereby reducing or eliminating variations in timing associated with serial process control. In such embodiments, a signal or measurement from the pressure sensor can be incorporated into a process control system: for example, information derived from a signal from a pressure sensor at a time during or before or after a dispense step can indicate a start or end of dispense of a process solution, and that indication can be a reference point to precisely control the timing of later steps in the process. Such a process can offer improvements over other process control methods, especially improvements in process control and in controlling timing of process steps that occur subsequent to a dispense step.

Conventional spin-coating process control systems introduce timing variations into spin-coating processes. These variations can be significant enough to cause noticeable variations in the inter-wafer and intra-wafer thicknesses of process solutions coated on the substrate. In one example, timing variations introduce variations in line width repeatability of a spin-coated photoresist. This can be caused by variations in the thickness of the spin-coated photoresist solution, variation in timing factors over which a developer solution is spin-coated and remains on the photoresist solution, or, most noticeably, combined variations in thickness of the photoresist solution and timing of placing and removing the developer solution onto and from the photoresist solution.

In controlling a spin-coating process, maximum precision can be achieved with precise timing of events that make up the series of steps or events of the process. A precision process can be accomplished by measuring each step, event, or condition, etc., of a process using techniques and instruments that will provide maximum precision and accuracy. In this regard, embodiments of the invention relate to the use of a pressure sensor to measure pressure of a process solution as the process solution is being dispensed (including slightly before and after actual dispense), and the incorporation of that pressure measurement into a process control system, e.g., to detect a beginning of a dispense or an end of dispense of a process solution.

Conventional process control techniques measure the end of a dispense by various means that are relatively inaccurate due to variabilities inherent in systems used to dispense process solutions. Causes of such variabilities can include: lag-time in the process control system and between the process control system and the spin-coating system, and variability and imprecision of physical and mechanical components of the spin-coating system such as pumps, dispense lines, and valves. As noted elsewhere in this description, even timing differences that are minutely small enough to be seemingly insignificant can affect the thickness or uniformity of a spin-coated process solution. Therefore, even small improvements in timing such as that provided by eliminating variabilities caused by mechanical factors of a dispensing system can result in measurable improvement in coating uniformity.

According to embodiments of the invention, a pressure sensor in a process solution dispense line can be incorporated into a process control system, e.g., to reduce timing variabilities within a process or among a series of process steps. The use of a pressure sensor in a dispense line allows monitoring of the actual flow of a process fluid directly, instead of detecting an event related to a dispense or control element of the spin-coating apparatus, e.g. actuation or de-actuation of a pump or valve. Measuring this fluid response (pressure) directly can reduce or eliminate timing variations that are otherwise inherent in measuring fluid dispense indirectly. The inventive method thereby provides more precise measurement of timing of an actual dispense step, and allows more precise control and timing of a spin-coating process.

Additional variation in timing of a spin-coating process (beyond inherent variation caused by mechanics and physical components of a spin-coating system) is caused by certain process control systems. Serial-style, e.g., round-robin-style, process control systems cause timing variations because process parameters are addressed sequentially through a series of subroutines in a predetermined, fixed fashion. At each subroutine, conditions may be monitored or data collected, recorded, and (if required by the programmed instructions) acted upon; the updated data may be passed on to the next subroutine. An example of a simple round-robin algorithm is shown in FIG. 3. This process control arrangement moves through a continuous path (shown as circular) from one subroutine to the next. Each subroutine addresses one or more different parameters (e.g., through sensors or by addressing hardware) of the spin-coating system. Examples of parameters that might be addressed by a subroutine might include temperatures of various components, such as chuck temperature, solution temperature, or ambient temperature; whether or not a process step has started or been completed, e.g., start or end of dispense; process chemical temperature control; a timer; the spin motor (checking for speed or acceleration); a pump; dispense lines; dispense arm (position); and general conditions inside of the spin-coating system.

To present an example of timing variability inherent in a system controlled using this type of a serial control system, consider a process wherein the process control system calls for spinning a turntable at the end of a dispense of process solution. The exact moment when the end of dispense occurs cannot be predicted. The moment of the end of the dispense will not be known until some time after the end occurs, and will likely occur at a moment when the computer is addressing any one of the other subroutines unrelated to the turntable or the dispensing system. Referring to FIG. 3, subroutine 1a checks whether the end of a dispense step has occurred, and if so starts turntable acceleration to a final spin speed. If the end of dispense has occurred, for example, while the CPU was addressing subroutine 1f, relating to the dispense arm, the CPU does not act on the end-of-dispense information until the remaining subroutines are addressed, e.g., through subroutine 1p. This may take a time in the range of tens of milliseconds, e.g., up to 30 or 50 milliseconds (e.g., for POLARIS® Microlithography Cluster spin-coating system from FSI International of Chaska, Minn.), or even more, depending on the specific machine, process control system, the lengths of the different intervening subroutines, and the number of subroutines that the CPU must traverse after the actual end of dispense in getting to the subroutine where such information will then be acted upon (here, 1a).

A millisecond-range time delay may sound insignificant. Consider, though, that when dealing with extremely small dimensions and tolerances related to modern spin-coated materials used in processing microelectronic devices, millisecond-range time delays can become truly significant. Timing delays in these ranges can produce detectable variations in thickness and uniformity of a spin-coated process solution, or of a further processed substrate of the coating, as measured, for example, as line width repeatability (inter-wafer and intra-wafer). In spin-coating a photoresist material, timing variations in the millisecond range have been found to cause thickness variations in a spin-coated photoresist layer, measured right before exposure, in the neighborhood of 1.3 Angstroms per 10 millisecond delay. When applying developer solution using spin-coating methods, timing variations in the millisecond range have been found to cause variations in line width repeatability of a patterned photoresist layer in the neighborhood of approximately 1 Angstrom per 10 millisecond delay. These amounts are significant.

Another significant problem with serial, e.g., round-robin-type, process control systems is that not only do they introduce variation in the timing or execution of a single step or action of a spin-coating process, but, serial-type process control will also carry that variation to subsequent steps, allowing variations to accumulate. FIG. 9 illustrates an example of how timing variations in serial processes can accumulate through a process as variation in the timing of earlier process steps or events are carried downstream to affect subsequent process steps (see also generally FIGS. 4 and 5, which show exemplary processing steps). In a serial process, the beginning of one step is based on the end of an earlier step or event. This often occurs over a series of steps within the spin-coating process. In FIG. 9, an exemplary generic spin-coating process proceeds through steps including step 1 (e.g., dispense), step 2 (e.g., accelerating spin), and step 3 (e.g., movement of dispenser) (FIG. 4 shows these steps more specifically). The x-axis of FIG. 9 shows timing of the series of steps, with the start of each step (beginning with the second step) being prompted by the end of the previous step. As such, FIG. 9 shows that at the end of step 1, the computer recognizes the end of the step and initiates the command for step 2. Likewise, at the end of step 2, the computer recognizes the end of the step and initiates the command for step 3. This continues through the programmed series of consecutive process steps.

As is illustrated in FIG. 9, variability of successive steps in a serially-controlled spin-coating process accumulates as the program moves through each step. The occurrence of the end of step 1 (e.g., process solution dispense) will be detected and acted upon at some time within 50 milliseconds (0.050 s) after it actually occurs. If the event actually occurs at exactly 1.00 second after the timer begins, the system will detect and use the information at a time within a period from 1.00 to 1.05 seconds. Step 2 is initiated upon detection of the end of step 1. Step 2 introduces its own timing variability of around 50 milliseconds (0.050 s) and if step 2 is programmed to complete at a time of 2.00 seconds, step 2 will complete and be detected at a time in the range from 2.00 to 2.10 seconds. The end of a third step initiated from the end of the second step will include yet another layer of variability added to the first two, e.g., a variability of up to 0.15 seconds.

In short, when the timing of subsequent events or commands of a spin-coating process are related to the timing of preceding events, as in standard serial-type process control systems, the variability in timing of each step accumulates as the process proceeds through consecutive steps. The result of these variations, especially when compounded through a series of steps, can be variation in the intra-wafer and inter-wafer properties of materials applied by spin-coating, or coated substrates. For example, substrates spin-coated with photoresist using serial or round-robin-type control programs can have photoresist film thickness variations of up to +/−25 Angstroms (3 sigma) when measured after soft bake and prior to exposure. In applying a developer solution using spin-coating techniques, variations in timing within these ranges can cause variation in line width repeatability of a developed photoresist film of about 8 nanometers (nm) inter-wafer, and about 10 nm intra-wafer (3 standard deviations).

A process control system that uses parallel control can reduce variabilities in timing of dispense and subsequent process events, film coating thickness, and line width repeatability, by eliminating lag time between steps in serial process control. Parallel control can eliminate process delays that occur between the time when an event (i.e., a triggering event) occurs and the time when the event is detected and used to initiate a subsequent process command. Parallel control also avoids initiating a series of process steps that base the beginning of a following step on the end of an immediately preceding step. Instead, process steps can be individually timed and executed in parallel, e.g., separately, using separate timers to measure individual durations. This means that a process control system using parallel control can avoid accumulation of timing variability caused by controlling a series of subsequent process steps according to an earlier process step or event. For example, parallel process control can independently control the timing of multiple durations measured from a single spin-coating process event, to interrupt subsequent serial control and initiate one or more subsequent process commands. E.g., upon receipt of a first interrupt signal, a parallel process control system can execute an interrupt service routine (ISR) that contains instructions for two or more timers that are initiated at the same time zero, the ISR using one separate timing device for each measured duration. Upon reaching the end of the duration for each timer, the process control is again interrupted to execute a predetermined process command, and thereafter resumes serial process control. When the end of the second duration is reached, control is again interrupted to execute the second process command, and so on, for as many timers and process commands as are included in the interrupt service routine.

Advantageously, parallel control allows the timing of multiple process commands to be independently controlled and executed at a time approximately within the accuracy of the timer. The durations are measured in parallel, not in series, so variabilities do not accumulate.

In brief, serial process control systems can cause 30 to 50 millisecond (0.030-0.050 s) delay for every step in a series of process commands, e.g., from the time after an event has occurred to before the occurrence is detected and acted upon. This amount of variability can be caused by imprecision in the process control system, and additionally by less than perfectly accurate detection of a start or end of a dispense step caused by indirect measurement of the start or end of such a step. These variabilities, separately or together, can be significant in affecting the uniformity of a sequence of spin-coating steps, their timing, and of spin-coated materials, but become more significant as variabilities accumulate due to the starts of later steps being based on the ends of a series of previous steps. Parallel, interrupt-driven process control methods can allow 5 millisecond variation or less in any one step, early or late in a sequence, thus reducing the variability in timing of individual process steps. Furthermore, with parallel timing of one or more durations of a spin-coating process, accumulation of even these reduced variabilities through a series of process steps can be eliminated.

The use of a pressure sensor in spin-coating systems and methods of the invention can improve the timing and precision of a spin-coating process using any type of process control system, e.g., serial process control such as round-robin control, or (preferably) parallel process control. A spin-coating system and process control system incorporating a pressure sensor according to the invention can preferably operate using parallel process control, wherein the process control system is programmed to be interrupted upon a trigger event, and interrupted subsequently at durations measured from the time of the trigger event, upon which subsequent interruption the system will promptly perform the next process command, i.e., without delaying by addressing intervening subroutines of the serial process. The process command can preferably be a command whose timing affects quality, e.g., uniformity, of a spin-coated material. The uniformity of application of the spin-coated material is improved, because the interruption and prompt execution of the process command avoids delay associated with serial-style process control. The trigger event may be but is not necessarily related to a pressure of process solution measured using a pressure sensor as described herein, such as a beginning or end of dispense of a process solution measured by a pressure sensor located at a process solution dispense line.

The process control methods of the invention can be used in processes of spin-coating any process solution onto a substrate, such as processes that incorporate spin-coating photoresist solution and optional solvent solutions onto a substrate; processes of spin-coating developer solution onto a substrate, optionally also including spin-coating deionized water onto a substrate; and processes that involve two or more of these, e.g., first spin-coating a photoresist solution onto the substrate and then a developer solution onto the photoresist. The substrate, photoresist, and developer can be otherwise processed as desired. The described process can provide improved coating uniformity, timing, and impact upon a substrate, of a process solution spin-coated onto a substrate, which provides for particularly uniform thickness of a developed and patterned photoresist layer. When a developer solution is applied in this manner over a spin-coated photoresist material, and wherein each spin-coating process uses interrupted timing methods as described herein, uniformity of the photoresist layer (when measured after soft bake and before exposure) can be as little as or less than 15 Angstroms (3 sigma) preferably less than 5 Angstroms (3 sigma) (for both intra-wafer and inter-wafer). The process can also produce a photoresist coating having line width repeatability of from 9 nanometers (3 sigma) intra-wafer and 6 nanometers (3 sigma) inter-wafer, measured after a hard bake. These values should be even better when a pressure sensor as described herein, e.g., measuring process solution pressure in a dispense line, is used to measure a start or end of dispense of a photoresist solution, a developer solution, or another process solution used in these spin-coating processes, and information from that pressure measurement is used in a parallel-style process control system.

Generally, the invention contemplates spin-coating methods, apparatus, and systems capable of operating with process control methods that involve the use of a pressure sensor, and preferably but not necessarily that also incorporate parallel process control. In one embodiment, a spin-coating process and apparatus can incorporate a pressure sensor to measure pressure of a process solution in a dispense line during and near the time of dispense, preferably to detect the start or end of dispense of a process solution. Additionally, interrupted process control can be used to control at least a portion of a spin-coating process subsequent to dispense, preferably using multiple timers in parallel. Most preferably, a hardware interrupt causes a process control system to enter an interrupt service routine which instructs the system to use interrupted timing control, with parallel timers, to execute one or more subsequent time-sensitive commands. The interrupt service routine includes the steps of setting two or more timers to run in parallel during the interrupt service routine for durations preferably starting together at the time of the trigger event. Subsequent process commands (which may or may not be, but can preferably be time-sensitive process commands) are executed at the end of each duration. In one embodiment, the interrupt service routine can be triggered by a signal from the pressure sensor; e.g., in spin-coating a photoresist solution a trigger event can be the end of dispense of a process solution used in the photoresist spin-coating process, such as the end of photoresist solution dispense or the end of a solvent dispense; in spin-coating a developer solution a trigger event can be a beginning of dispense of a process solution used in coating developer solution, such as a beginning of developer solution dispense or a beginning of deionized water dispense.

An aspect of the invention relates to a spin-coating system that includes a supply of process solution in fluid communication with a dispenser through a dispense line, and a pressure sensor that measures the pressure of the process solution in the dispense line. The pressure sensor can be any device capable of measuring pressure of a process solution, and can preferably be or include a pressure transducer. According to the invention, the pressure sensor can measure pressure of the process solution in the dispense line at a time related to a step of dispensing process solution, for example to detect a beginning or an end of the process solution being dispensed by the dispenser, e.g., onto a substrate, to control timing of a subsequent spin-coating process step.

Another aspect of the invention relates to a spin-coating system that includes at least: a turntable to support and rotate a substrate; a dispenser moveable between a dispensing position and a non-dispensing position; a supply of process solution in fluid communication with the dispenser through a dispense line; a pressure sensor that measures the pressure of the process solution in the dispense line, for example but not necessarily at a time related to a step of dispensing process solution, e.g., to detect a beginning or an end of process solution being dispensed from the dispenser; and a process control system that controls application of the process solution to the substrate, the process control system being programmed to interrupt serial control to execute a process command.

Yet another aspect of the invention relates to a control system for controlling a spin-coating apparatus. The control system measures pressure of a process fluid, e.g., at a beginning or end of a process solution dispense, based on a pressure of the process solution, e.g., in a dispense line. The pressure reading is used to control subsequent process steps.

Yet another aspect of the invention relates to a method of spin-coating a process solution onto a substrate such as a semiconductor wafer containing microelectronic devices and integrated circuits. The method includes providing a spin-coating system that includes a supply of process solution in fluid communication with a dispenser, dispensing the process solution through the dispenser to the substrate, and measuring the pressure of the process solution to detect a beginning or an end of dispense of the process solution at the dispenser.

Still another aspect of the invention relates to a method of spin-coating a photoresist onto a semiconductor wafer. The method comprises the steps of spin-coating a photoresist solution on a surface of the semiconductor wafer, and spin-coating a developer solution on the photoresist material, wherein the method includes using a pressure sensor to measure one or more of the beginning or end of dispense of the photoresist solution or the beginning or end of dispense of the developer solution.

Yet another aspect of the invention relates to a method for controlling a spin-coating process for applying a process solution onto a substrate using a spin-coating system, the spin-coating system comprising a supply of process solution in fluid communication with a dispenser through a dispense line, and a pressure sensor that measures pressure of the process solution in the dispense line at a time related to a step of dispensing process solution, to control timing of a subsequent spin-coating process step. The method comprises controlling the process using serial process control wherein the process is controlled by sequentially executing a series of subroutines, and interrupting the serial process control with an interrupt signal to execute a process command. In preferred embodiments, the interrupt signal relates to a beginning or an end of dispense of a process solution at the dispenser, measured by pressure of the process solution in the dispense line.

Yet another aspect of the invention relates to a method for providing a photoresist on a substrate using a spin-coating system. The spin-coating system comprises one or more spin-coating apparatuses that collectively contain a supply of photoresist solution in fluid communication with a photoresist solution dispenser through a photoresist dispense line, a supply of developer solution in fluid communication with a developer solution dispenser through a developer dispense line, a photoresist solution pressure sensor that measures the pressure of the photoresist solution in the photoresist solution dispense line, and a developer solution pressure sensor that measures the pressure of the developer solution in the developer solution dispense line. The method comprises spin-coating the photoresist solution to the substrate, wherein the spin-coating process is controlled by a method comprising: controlling the process using serial process control sequentially executing a series of subroutines, and interrupting the serial process control with an interrupt signal to execute a process command; and spin-coating the developer solution to the photoresist, wherein the spin-coating process is controlled by a method comprising: controlling the process using serial process control sequentially executing a series of subroutines; and interrupting the serial process control with an interrupt signal to execute a process command.

Still another aspect of the invention relates to a method of controlling a spin-coating process using a spin-coating system comprising a supply of process solution in fluid communication with a dispenser through a dispense line and a pressure sensor that measures the pressure of the process solution in the dispense line. The method comprises the use of a process control system programmed with an interrupt service routine. Upon a trigger event comprising a beginning or an end of dispense of the process solution as measured using the pressure sensor, a hardware interrupt is sent to the process control system, and upon receiving the hardware interrupt, the process control system executes an interrupt service routine.

Another aspect of the invention relates to a spin-coating system comprising a supply of process solution in fluid communication with a dispenser through a dispense line, and a pressure sensor that measures pressure of the process solution to detect a malfunction (e.g., minor or major irregularity, abnormality, or breakdown of equipment or a condition) in the apparatus.

Still another aspect of the invention relates to a method of detecting a malfunction (e.g., irregularity) in a spin-coating apparatus, the method comprising measuring a pressure of a process fluid. The measured pressure can be compared to an expected or otherwise normal pressure, to identify a difference between the expected and the measured pressure, to indicate a malfunction (e.g., abnormality or irregularity).

### BRIEF DESCRIPTION OF THE DRAWINGS

FIG. 1 illustrates an embodiment of a spin-processing apparatus that includes a pressure sensor.

FIG. 2 illustrates an embodiment of a spin-processing apparatus that includes a pressure sensor.

FIG. 3 is a diagram illustrating an exemplary round-robin-type control algorithm.

FIG. 4 is a diagram of steps of spin-coating a photoresist solution onto a substrate using a spin-coating system.

FIG. 5 is a diagram of steps of a process for applying a developer solution onto a substrate using a spin-coating system.

FIG. 6 illustrates interrupted control of a portion of the steps of the diagram of FIG. 4.

FIG. 7 illustrates interrupted control of a portion of the steps of the diagram of FIG. 5.

FIG. 8 illustrates a timeline of steps of a process controlled using interrupted timing, in particular interrupted timing with multiple timers controlling different durations in parallel.

FIG. 9 is a diagram illustrating the introduction of timing variabilities in a sequence of spin-coating process steps controlled using serial process control.

FIG. 10 is a plot of fluid pressure in a dispense line showing, among other things, the start and end of dispense of process fluids.

### DETAILED DESCRIPTION

Spin-coating or spin-processing are methods of applying a process solution onto a substrate as a substantially uniform film or coating.

A variety of substrates can be processed using spin-coating techniques. These include microelectronic devices such as integrated semiconductor circuits (e.g., semiconductor wafers that contain microelectronic devices), display screens comprising liquid crystals, electric circuits on boards of synthetic material (circuit boards), and other commercially significant materials and products.

The process solution can be any material known to be usefully applied or coated onto a substrate using spin-coating techniques and apparatuses. Examples include photoresist solutions and developer solutions used in photolithographic methods, as well as other process solutions optionally applied to a substrate during photoresist or developer solution spin-coating. The invention also contemplates the application or coating of other materials using spin-coating methods, such as the application of spin-on dielectrics, spin-on glass, spin-on dopants, or low k dielectrics, or developer solutions commonly used with any of these. As an example, the invention may be used to apply a photodefinable spin-on dielectric material such as a polyimide, and/or a developer solution for such a material. Thus, while processes of the invention are described herein mainly in the context of semiconductor wafers and photolithography, especially of spin-coating a photoresist solution, followed by spin-coating a developer solution, the invention is not limited to such specific applications. Examples of other process solutions that may be used in spin-coating process steps either alone or as part of coating a different material such as a photoresist or a developer solution, include solvents such as organic solvents, cleaners, and water (e.g., deionized water).

Semiconductor wafers can be spin processed, e.g., in combination with photolithographic methods and materials, using one or more steps that involve spin-coating. Exemplary steps involved in processing to deposit a patterned photoresist material onto a substrate can include one or more of cleaning or priming a surface; heating or chilling (once or multiple times throughout a sequence of steps in a larger process); applying photoresist solution to a substrate; exposing the photoresist material, e.g., using a mask and radiation; additional heating and chilling steps; application of a developer solution using spin-coating techniques, along with rinsing away the developer solution and regions of photoresist to leave behind a patterned photoresist; and final beating and chilling, if desired. An exemplary series of one variation of such steps is provided below.

During a photoresist spin-coating step, one or multiple different process solutions may be applied to a substrate. Examples include the photoresist solution itself, as well as solvents, many of each of which are well known in the arts of microelectronic processing. Solvents may be useful in a photoresist coating step for top and bottom edge bead removal, topside substrate conditioning, and photoresist strip. The particular amount, timing, and composition of solvent dispensed in a process of spin-coating a photoresist solution may depend on factors such as the type and purpose of the solvent, the type of substrate, and the particular photoresist solution used. Examples of edge bead removal, conditioning, and strip solvents include PGMEA (propylene glycol mono-methyl ether acetate), PGME (propylene glycol mono-methyl ether), and EL (ethyl lactate). Other solvents may be useful for different reasons, such as solvents to clean a spin-coating apparatus, e.g. bowl wash solutions and exhaust rinse solutions. (For solutions not used during time sensitive process steps, such as cleaning solvents, the pressure sensor as described herein could be used as a malfunction monitor and flow detector, if not for process control information.) According to the invention, pressure of any one or more of these process solutions may be monitored using a pressure sensor as described herein, preferably by measuring pressure of the process solution in a dispense line. Optionally, information from the measured pressure of any one or more of these process solutions can be used (separately or in combination) as described herein to monitor the apparatus (e.g., detect malfunctions), or for process control. For example, the pressure in a dispense line of any process solution can be used to detect a malfunction, or to identify a beginning or an end of a dispense step of the process solution. Information relating to the beginning or end of a process solution dispense can be used by a process control system, e.g., as a trigger event in a parallel control-type system, to control the timing of one or more subsequent process events.

A spin-coating sequence can begin by preparing a substrate for deposition of a photosensitive photoresist coating on a surface. Preparation might include cleaning, and often includes dehydrating with elevated temperature and reduced pressure, and priming the surface with a material that promotes adhesion between the substrate surface and the photoresist material, e.g., hexamethyldisilazane (HMDS).

A next step might involve bringing the temperature of the wafer to ambient, for instance by chilling the wafer using conventional methods and equipment such as a chill plate.

Next, a photoresist material can be applied to the substrate, preferably as a thin, uniform film. The photoresist may be applied using any of a variety of known and useful techniques, including lamination, extrusion techniques, spray-on coating techniques, chemical vapor deposition, and others. Preferably, in the practice of one embodiment of the invention, the photoresist is spin-coated onto the substrate using an apparatus that incorporates a pressure sensor in a dispense line to detect pressure of the photoresist during dispense, especially to detect a beginning or end of dispense, most especially with respect to a photoresist solution, to detect the end of dispense of the photoresist solution. Other process solutions, such as solvents, can also be applied to a substrate in a process of spin-coating a photoresist solution. The dispense pressure of a solvent or other process solution may additionally or alternately be measured using a pressure sensor. The beginning or end of dispense of one or more of these process solutions may be detected and that information may be used to control one or more subsequent process events. Most preferably the apparatus and methods also incorporate parallel process control methods.

The spin-coated photoresist can be coated to have a desired thickness chosen based on the needs of the device for which the substrate is designed. Typically the layer can be considerably thin, for example of a thickness in the range from 50 microns to 0.5 microns, or less. Additional information relating to preferred details of a photoresist solution spin-coating process in the context of using process control according to the invention, is provided infra.

After application of photoresist solution in the form of a spin-coated layer, a typical next step is to drive solvents from the spin-coated photoresist solution, for example by baking. This step is sometimes referred to as a “soft bake” or “post-apply bake.” The exposure time and temperature can be any that are effective to drive solvents out of the photoresist solution.

Following a post-apply bake, the temperature of the substrate can be reduced, for example to ambient temperature, optionally with the use of a chill plate.

The photoresist material, effectively eliminated of solvent, can be selectively exposed, e.g., through a mask, to a source of energy to cause reaction of portions of the photoresist, as is known in the arts of semiconductor wafer and microelectronics processing. A mask may be any type known to be useful with a selected substrate, photoresist, and process. Any of various well-known types of masks and masking techniques and equipment can be useful. The radiation may be any form or wavelength of radiation, and should be chosen according to the chemistry and design of the photoresist solution. Preferred radiation is often of a single wavelength, i.e., monochromatic, because many preferred photoresist materials are monochromatically curable.

After radiation exposure, a typical next step can be to again raise the temperature of the substrate and the exposed photoresist. This time heating may be performed for reasons such as to address standing wave phenomena using a diffusion mechanism for exposed versus unexposed regions and/or to complete a chemical reaction of the photoresist material, e.g., for chemically amplified photoresists. This typically can be accomplished with a “post-exposure” bake, which can be followed by returning the substrate to ambient temperature, optionally with the use of a chill plate.

A developer solution can additionally be applied to the photoresist-coated substrate surface by spin-coating. According to the invention, this step can be accomplished using methods and apparatus that incorporate a pressure sensor in a developer solution dispense line to monitor pressure of the developer solution during dispense, e.g., to detect the beginning or end of dispense of the developer solution, most preferably the start of the dispense. Optionally, deionized water can be applied to the substrate with developer solution during spin-coating of developer solution. In addition to or instead of measuring developer solution pressure, the dispense pressure of deionized water may be monitored as described herein, e.g., to detect a beginning or end of dispense, and related information may be used for subsequent process control. Also preferably, the process can incorporate process control that involves an interrupt-driven, parallel control method, as described herein, wherein the control method makes use of the information from the pressure sensor that measures pressure of, e.g., developer solution or deionized water.

The developer “develops,” e.g., reacts with, breaks down, or dissolves, either the exposed or the unexposed portion of the photoresist material, allowing one or the other of the exposed or unexposed photoresist materials to be washed away and removed, leaving behind a patterned photoresist.

Developer solutions are well known, and according to the invention can be any of a variety of compositions that effectively and selectively react with, break down, or dissolve a material previously applied to a substrate, e.g., photoresist. When developing an applied photoresist solution, this allows selective removal of a region of photoresist, leaving behind a patterned photoresist layer. Such developer solutions are known in the semiconductor wafer processing art. Some are considered to be specifically useful with certain types of photoresist materials and may be matched with the use of those photoresists. Examples of useful types of developer solutions include water-based materials, e.g., aqueous caustic compositions such as aqueous tetra-methyl ammonium hydroxide (TMAH). Other developer compositions include sodium hydroxide or potassium hydroxide solutions, e.g., aqueous sodium hydroxide or aqueous potassium hydroxide. A developer solution might also include other materials that will facilitate developing or removal of a photoresist, e.g., surfactants.

After application of the developer solution, the substrate can optionally be baked (the “hard bake”) and chilled once again.

Equipment generally useful for performing spin-coating processes are known in the arts of photolithography and semiconductor or microelectronics processing, and includes spin-coating systems, chill plates, hot plates, ovens, etc. Such types of equipment are commercially available, and are often sold and used together in “clusters” for efficient processing of multiple steps between different pieces of equipment. A preferred spin-coating system for coating photoresist and/or developer solution is of the type sold by FSI International, of Chaska, Minn., under the trade designation POLARIS® Microlithography Cluster.

According to the invention, a system for supplying a process solution to a spin-coating system can include a pressure sensor to measure pressure of process solution in a dispense line. The pressure measurement can be used during the spin-coating process, e.g., to identify information related to a step of dispensing a process fluid, e.g., to monitor, detect, or identify a beginning or an end of a dispense of a process solution, or to detect and monitor other proper functioning of the dispensing apparatus and spin-coating apparatus generally.

In a spin-coating process, the identification, with maximum practical precision, of the timing of the end of a step of dispensing a process solution, can be useful to improve the precision of individual steps of the spin-coating process, thereby improving precision of the overall process. Dispensing a process solution, particularly a beginning of the dispense, is accompanied by an increase in pressure of the process solution at the dispenser and in a dispense line leading to the dispenser. An end of a dispensing step is accompanied by a reduction in the pressure of the process solution in the dispense line. Accordingly, the beginning or end of a dispensing step may be detected or identified by correlating the pressure in the dispenser or componentry upstream from the dispenser, e.g., dispense lines, to the dispensing of the process solution.

FIG. 10 illustrates how process solution dispense events can be measured using a pressure sensor at a process fluid dispense line. Line Z indicates a measured reference pressure (about 0.008, as a raw voltage produced by the pressure sensor—one of skill will understand that this raw voltage could be used as described herein, or could be converted to other units, e.g., engineering units of pressure) of process solution in a dispense line. This may approximate a pressure in a dispenser or dispenser componentry when no dispense event is occurring, e.g., a static pressure.

As a reference, line C indicates a signal produced by an optical sensor programmed to visually detect a start and an end of a dispense step at the point of dispense in the dispenser.

Line A of FIG. 10, the rectangular wave, shows theoretical start of dispense and end of dispense events, based on a signal from the dispenser. (In the figure, line A represents an electrical signal from the dispenser that indicates when the dispenser believes the start and end of dispense have occurred. This is a digital signal, usually between about 0 to 5 volts. It has been scaled here to fit on the chart.) A start of dispense (SOD) event is illustrated at time zero by the SOD signal moving from near 0.26 to about 0.96 on the Y-axis on the left of the figure. The dispense occurs over a time of about 2 seconds, after which the end of disperse (EOD) signal returns to the lower level.

Line B of FIG. 10 illustrates a pressure of a process solution in a process solution dispense line as the pressure changes from at or before a start of dispense, through the dispense, and at and slightly after the end of dispense. Shortly after time zero, which is the theoretical start of dispense, pressure increases from the Zero Reference to a (measured or actual) dispense pressure (about 0.025 to 0.030—measured as a raw voltage) (this increase is referred to as profile I of line B). The time lag X from time zero to the initial pressure increase may be due to variabilities in the spin-coating device that can be preferably minimized. The pressure increase from the Zero Reference to the dispense pressure produces a profile (I), information from which can be used for process control. After the beginning of dispense pressure increase, during dispense, the pressure hovers about the dispense pressure range (the periodic bumps in this plateau are caused by the control system of the dispense pump). Following the theoretical end of dispense, (EOD), starting just after about 2 seconds, the pressure returns to the Zero Pressure Reference over profile II. The profile II of the return to the Zero Pressure Reference at the end of dispense is somewhat more gradual than the start of dispense pressure increase, because at the end of dispense, a control valve is used which creates the particular return to Zero Pressure Reference.

The actual shape of the increase and decrease in pressure profiles I and II are not particularly important. Instead, of import is the ability to monitor and measure each pressure profile according to the invention, and the ability to use a pressure measured at a point of either profile to act as a triggering event in a process control system. Specifically, each of the increase and decrease profiles relate to the mechanisms used to begin and end the dispense. A point in one or both of the profiles I and II can be selected to detect a beginning or end of a dispense, respectively. For example, a measured pressure of 0.014, 0.020, or any other arbitrary pressure along profile I (the “Pressure Sensor Response”), can be selected to indicate that a start of dispense has occurred. This information can be sent to a process control system for use in controlling one or multiple later processing events such as end of dispense; movement of a dispense arm; or beginning or ending of substrate acceleration; etc. Likewise, a point of the end of dispense profile (II) can be selected to indicate an end of a dispense event, e.g., 0.015, 0.020, or even 0.000 (voltage, as measured). As yet another possibility, a point of the oscillating return to Zero Pressure Reference, e.g., a point in profile III, can be used to indicate an end of dispense.

Measured process solution dispense pressure profiles will typically share similar patterns for different spin-coating apparatuses and process fluids. Different profiles should have a start of dispense increase from Zero Reference to dispense pressure, an end of dispense pressure decrease from dispense pressure to Zero Reference (optionally with oscillations about the Zero Reference), and a relatively level dispense pressure during the dispense. On the other hand, the specific pressure profiles that occur during the start of dispense increase, the end of dispense decrease or oscillation, or the dispense portion, can be relatively varied depending on factors relating to the spin-coating system, the dispense system, and the process fluid.

Again, the actual shape of any of these profiles is not of high importance, as long as a point in a profile can be selected for detection of a start or end of a process solution dispense. The profiles of line B should occur consistently and with repeatability, including profiles I, II, III (if used), and the dispense profile IV. Based on such consistent and repeatable profiles, any point of data can be used as information in a process control system, for example to be a basis for controlling one or more later process steps. In one preferred embodiment of dispensing a developer solution in a spin-coating process, a process control system can use a measured pressure that occurs during the start of dispense profile as an indication of a start of dispense event, e.g., a triggering event. In another embodiment of dispensing a photoresist solution in a spin-coating process, a process control system can use a measured pressure that occurs during the end of dispense profile II or the oscillation profile III as an indication of an end of dispense event, e.g., a triggering event.

FIG. 10 shows that the start of dispense (SOD) and end of dispense (EOD) signals happen before the actual start of dispense (or the end of the start of dispense profile I) and end of dispense (or the end of the end of dispense profile II), respectively. While these delays between the SOD or EOD signal and the actual start or end of dispense may be improved upon from the described exemplary system, the delays are caused by control system delays (which are considered repeatable) and delays in actuating pumps and valves used to control the fluid flow. Monitoring the pressure in the dispense line according to the invention allows more accurate measurement of when a start of a dispense or an end of a dispense actually occurs. This improved information relating to timing of dispense events can be used to improve process timing repeatability and process performance of subsequent spin-coating processing steps.

According to the invention, information found in FIG. 10 can be used in other ways as well. For example, information of a pressure graph or pressure trace as exemplified in FIG. 10 can be used to detect a malfunction, e.g., irregularity, abnormality, change, or other malfunction in process or equipment conditions. The malfunction may relate to any of a variety of minor, serious, gradual, or acute changes in processing or equipment conditions. The malfunction can be identified or detected by comparing (manually or electronically) an actual dispense profile to an expected or historical profile.

As an example, the area “under the curve” of line B of FIG. 10 will be related to, e.g., proportional to, the total volume of process fluid dispensed. If an area of an actual dispense profile is not as expected, the data can operate as a cross-check on the dispense pump and can be used to generate an error message or warning of a malfunction.

An example of a malfunction that can be detected in this manner is a dispense line that slowly or abruptly becomes plugged, causing the pressure reading (e.g., a point or portion of the pressure profile) during dispense to vary or to be different from expected. Another example of a malfunction could be a pressure leak, an equipment breakdown, etc. By monitoring pressure of a process solution during dispense, the invention may be useful to identify a plugged line or broken equipment not otherwise detected. Slight changes over time, or drifting, in the timing of a pressure value related to a particular point in the dispense step, relative to an expected value, a “normal” value, a historical value, or the timing of a start of dispense or an end of dispense signal from the dispense pump, can similarly be used to monitor the condition of the coating apparatus. Bounds can be set up, e.g., using software of the process control system, to identify and report an abnormal condition or drifting pressure value during dispense, such as any condition that drifts or is otherwise different from expected or normal.

It is important to note that the inventive method of monitoring pressure as exemplified by FIG. 10, to precisely identify a point (e.g., start or end) of dispense upon which to initiate timing control of later process steps, automatically compensates for and controls the timing of downstream events to compensate for process control or other changes that may occur in the timing of the initial step (“trigger step”). In addition, the invention also provides a way to monitor elements of the coating apparatus that directly or indirectly affect the precision and repeatability of the dispense step, and the pressure profile of process solution in dispense componentry at, before, during, and slightly after the dispense step occurs.

The pressure sensor can be any pressure sensor, known or developed, that can sense the pressure of a fluid such as a process solution. Examples of pressure sensors include pressure transducers such as a model number AB HP from Data Instruments, Acton, Mass., U.S.A. The pressure sensor can be located at any position in the spin-coating system that allows the sensor to measure pressure of a process solution to detect or identify information relating to a dispense step, such as a beginning or end of a process solution dispense step. A preferred position is in a process solution dispense or supply line relatively closer to the dispenser as compared to the supply of process solution, e.g., relatively close to the enclosure of a spin-coating apparatus, either inside or outside of the enclosure. In a system that includes a supply of process solution and a dispense valve in a dispense or supply line for controlling the dispense of the solution, the pressure sensor is most preferably downstream from the dispense valve, i.e., between the dispense valve and the dispenser.

The dispenser can be any known or developed dispenser. Dispensers are well known in the arts of spin-coating and photolithography, and examples include dispensers that include one or more of a dispense arm with nozzle attached, a dispense arm that retrieves separate nozzle(s), or fixed dispense nozzle(s).

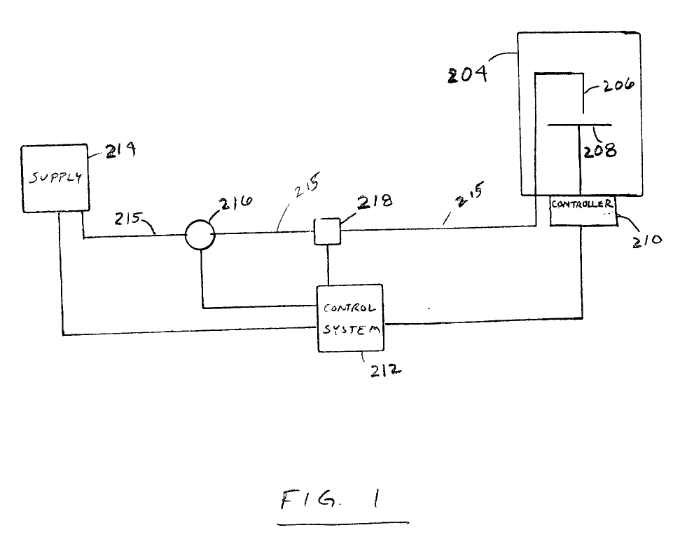

FIG. 1 illustrates an embodiment of an apparatus of the invention, a spin-coating system that includes a spin-coating chamber 204. Chamber 204 contains a dispenser 206, turntable 208, controller 210, and should include other necessary or optional componentry for monitoring and controlling the materials and environment of the spin-coating process. The system of FIG. 1 also includes a control system 212, a supply 214 of a process solution, a valve 216, and supply (or “dispense”) lines 215 connecting supply 214 to chamber 204 and dispenser 206. According to the invention, the system includes a pressure sensor 218 for measuring pressure of a process solution in dispense line 215. Valve 216 and pressure sensor 218 are illustrated in this embodiment as being connected to control system 212, as are controller 210 and supply 214. As shown, the pressure sensor 218 can be located outside of chamber 204, but may optionally be located inside of chamber 204. FIG. 1 does not show a pump for pumping a process solution from supply 214 to valve 216 and dispenser 206. A pump may optionally be used in various forms and with various controls and constructions. A pump is generally remote to the apparatus, and would typically be located as part of or near supply 214, upstream from valve 216.

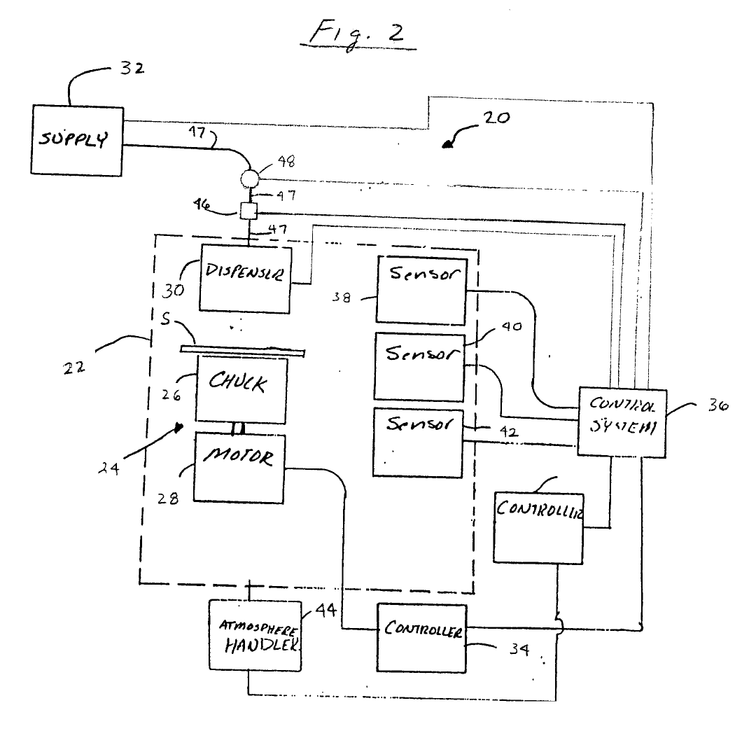

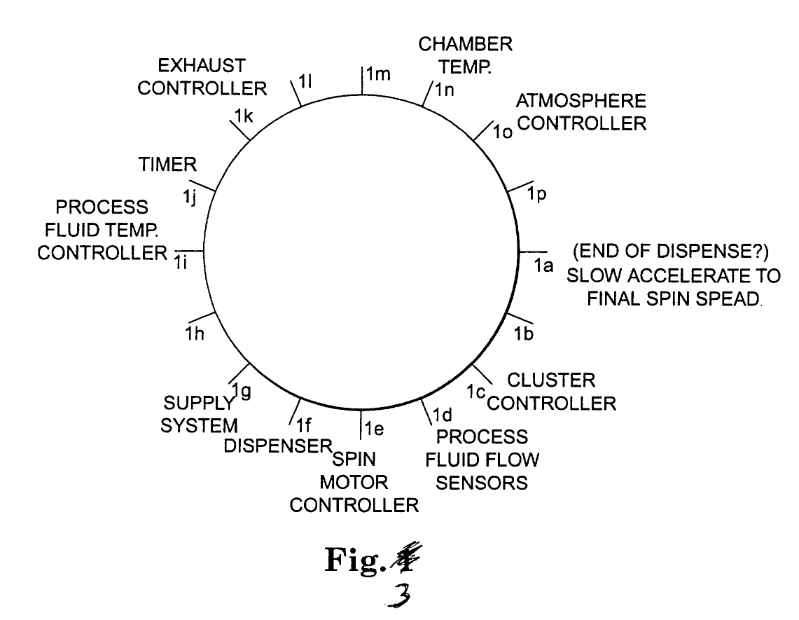

FIG. 2 is as a block diagram illustrating another embodiment of a spin-coating system according to the invention, for example as incorporated into a POLARIS® 2500 Microlithography Cluster spin-coating apparatus. System 20 is adapted to coat one or more process solutions onto a substrate. System 20 includes a chamber 22 housing a rotatable support 24 which includes a chuck 26 connected to a motor 28. A substrate S is mounted, e.g., by means of vacuum suction or the like (not shown) to chuck 26. The substrate S and chuck 26 are rotated by the motor 28 during steps of the spin-coating process.

Included in system 20 is a dispenser 30 for dispensing one or more process solutions (e.g., photoresist, deionized water, developer solution, solvents such as edge bead removal solvent, etc.) onto substrate S. Dispenser 30 can be of any design that allows application of a process solution onto a surface of substrate S. (Generally, the same spin-coating system is not used to apply both photoresist and developer solution). Optionally, a dispenser 30, e.g., at a dispensing arm, may have multiple dispensing nozzles to allow dispensing of two or more different process solutions from the same dispenser or dispensing arm.

Dispenser 30 can include a dispensing arm or manipulator (not shown) moveable between different positions to facilitate dispensing process solutions onto substrate S. A dispensing arm may be moved between a dispensing position where the arm is in a position generally over a surface of the substrate S, and a non-dispensing position where the dispensing arm is out of the way. As another example, especially when dispensing a developer solution, a dispensing arm may be moved over a rotating substrate while dispensing, to apply a developer solution in a circular or spiral pattern. In other embodiments, a dispenser or dispensing arm may include manifold dispensing points for a single process solution (e.g., developer solution) and may not require movement to apply developer solution in a circular or spiral pattern.

Dispenser 30 is connected to at least one supply system 32 for supplying one or more process solutions. Preferably, the spin-coating system includes at least one supply system (including supply lines, etc.) for each process solution used. Exemplary FIG. 2 shows apparatus 30 having a single supply system, 32, but two or more supply systems may be used, especially to supply different process solutions or other needed materials. Dispenser 30 and supply system 32 can be of conventional design and adapted to use conventional techniques to maintain materials in condition to be supplied through dispenser 30 onto substrate S. For example dispenser 30 may be connected to a heater (not shown) for maintaining a desired temperature of a process solution. Suitable dispenser and supply system components for use in a system such as that shown in FIG. 2 can be found in the POLARIS® Microlithography Cluster manufactured by FSI International, Inc., Chaska, Minn.

A supply system such as supply system 32 can optionally include components including a pump, lines, temperature monitoring and control mechanisms, filters, sensors such as temperature sensors, volumetric flow sensors, etc. (not shown). Also, supply system 32 can optionally and preferably be connected to a controller and to process control system 36, to provide preferred centralized control of the overall spin-coating process. Preferably, the supply system 32 can contain a pump (preferred), or another form of fluid mover such as a pressurized container, to cause fluid to become pressurized in the dispense line and, in coordination with the optional control valve 48, to flow through dispenser 30 as desired.

According to this illustrated embodiment of the invention, the system of FIG. 2 includes a pressure sensor 46 for measuring the pressure of a process solution flowing to dispenser 30 through a supply or dispense line 47. The system also includes a control valve 48 (optional) for controlling the dispense. Each of these, as well as dispenser 30, is shown to be connected to control system 36, for centralized control. In such a preferred embodiment of the invention, the distance between each of the dispenser and pressure sensor, and the pressure sensor and control valve, can be selected to be any useful distances. An example of a useful distance from the pressure sensor to the dispenser is from about 1 to about 4 feet.

FIG. 2 shows control system 36 that includes componentry, e.g., hardware, software, or combinations of both, that, with sensors, monitors, controllers, and features of the hardware, electronically controls a spin-coating system and spin-coating processes performed using the spin-coating system. Chamber 22 includes sensors (three in this embodiment) 38, 40, and 42, that provide signals to control system 36. Any one of sensors 38, 40, or 42, may relate signals of a process condition or event, such as a temperature, humidity, or pressure of the atmosphere, or of a property of a process solution supplied from supply system 32. Also, more or fewer than three (as illustrated) sensors may be used.

Apparatus 20, as exemplified, also includes an atmosphere handler 44 in fluid communication with chamber 22 and adapted to process the atmosphere in chamber 22 to desired temperature and humidity conditions, as well as to optionally provide desired air flow within the chamber to maintain desired (e.g., laminar) flow of atmospheric gases or other materials over a substrate. Atmosphere handler 44 may optionally include sensors (not shown) for sensing temperature, humidity, and air flow inside of chamber 22, or may be used with other sensors (e.g., 38, 40, or 42, used for sensing temperature and humidity).

Chamber 22 creates a spin-coating environment suitable for applying a process solution onto a substrate S, and which can be maintained and/or controllably adjusted. Temperature, humidity, and other such atmospheric or environmental conditions inside chamber 22 can be set at particular levels to reduce or eliminate variations in such conditions that would cause unpredictability in spin-coating. Chamber 22 also serves as a barrier against particulate and other contaminants, and can be used to control air flow at or near the surface of the substrate, to facilitate particulate removal. Chamber 22 and apparatus 20, particularly with respect to rotatable support 24, are generally adapted to allow access to the interior of chamber 22 so that a substrate S can be mounted on and removed from the chuck 26.

A suitable atmosphere within chamber 22 can depend on the type of coating process and process solution involved in a chosen spin-coating application. The atmosphere can be a vacuum, air, or an inert gas such as He, Ar, N₂, or the like, or a combination thereof.

Optionally and preferably a barometric pressure sensor can be located in or proximal to apparatus 20, e.g., within chamber 22, to measure some parameter indicative of the barometric pressure inside chamber 22, preferably in such a way that the measured parameter is indicative of barometric pressure near the substrate S. For example when using the POLARIS® Microlithography Cluster, a suitable placement is within the coating chamber (coater module), in a non-turbulent, shrouded position that eliminates air flow effects on the barometric pressure sensor. In a preferred embodiment, the barometric pressure sensor can be a PTB100B series analogue barometer manufactured by Vaisala Oy, Helsinki, Finland. The use of a barometric pressure sensor in a spin-coating process is described in Assignee's copending U.S. patent application Ser. No. 09/397,714, filed Sep. 16, 1999, incorporated herein by reference.

Process control system 36 uses signals from different components of the spin-coating system, e.g., sensors, controllers, hardware elements, etc., to control the system and spin-coating process performed using the system. Process control system 36 accepts input signals from such components and generates output signals based on the input signals. The output signals instruct and control the spin-coating process, preferably to cause desired and optimal spin-coating processing of materials onto a substrate. The apparatus may also incorporate other devices and methods useful in disposing a uniform coating of a process solution onto a substrate, as described, e.g., in U.S. Pat. Nos. 4,932,353; 5,066,616; 5,127,362; 5,532,192; each of which is incorporated herein by reference.

Control system 36 can be any electronic, programmable process control system useful to monitor and control a system, process, condition, or component, etc., relating to the spin-coating system. Control system 36 may comprise an electronic computerized processor such as a central processing unit (CPU) or a programmable logic controller (PLC), or the like, which preferably contains an internal clock. Random access memory (RAM) can preferably be used to store a software program containing instructions. One or more timers can be programmed into the RAM to measure durations by referencing the internal timer of the processor. External storage devices such as a floppy disk drive, CD ROM, or the like can optionally be electronically connected to the processor for transferring information in one or two directions. The process control system is electronically connected to the spin-coating system, e.g., to hardware or controllers thereof.

Process control methods, some including synchronization, are described, for example, in Applicants' copending U.S. patent application Ser. No. 09/583,629, entitled “Coating Methods and Apparatus for Coating,” filed May 31, 2000, which is incorporated herein by reference. Exemplary spin-coating process control methods include what are referred to as the “round-robin” method, and the “serial” method.

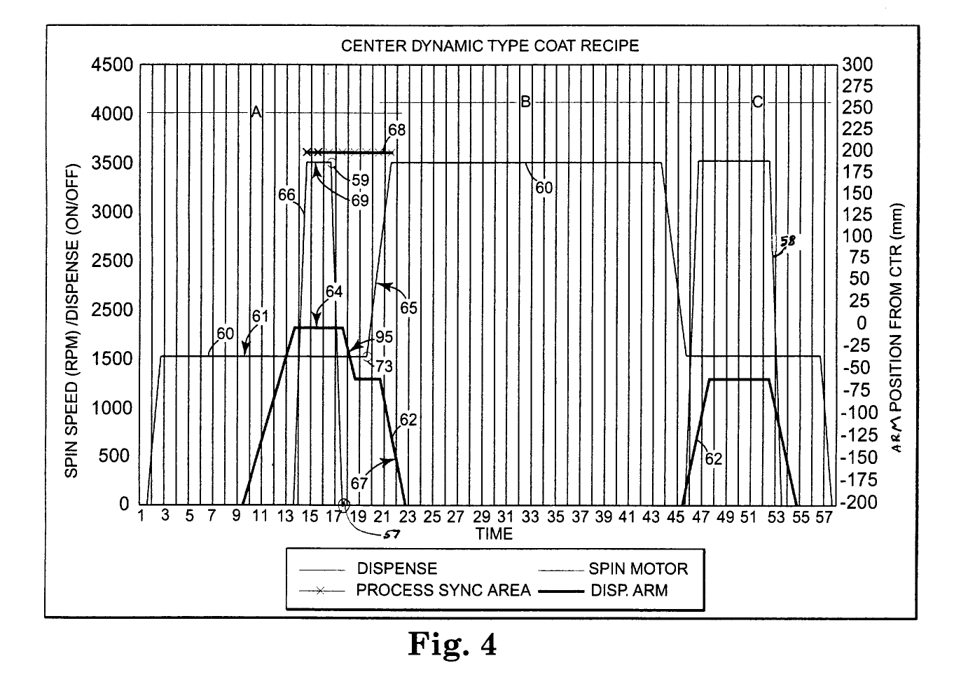

FIG. 4 illustrates typical steps involved in spin-coating a photoresist solution onto a substrate. Line 60 represents the rotational speed of the spin motor through the process. Line 62 represents the position of a dispense arm. Line 66 represents the dispensing of photoresist solution onto the substrate. Crossed line 68 identifies a “time-sensitive portion,” which means that it includes one or more “time-sensitive steps,” the timing of which has been found to show measurable effects on the thickness and/or uniformity of a spin-coated photoresist.

The process can proceed generally as follows. Once a substrate is installed into the apparatus, a process for spin-coating a photoresist solution can include three general portions: dispensing an amount of photoresist solution onto the substrate (dispensing portion -A-), casting the photoresist to form a uniform film (-B-), and removal of edge bead/backside rinse (-C-). (These portions being generally defined, their boundaries are not exact.)

In dispensing portion -A- photoresist solution is applied to a surface of a substrate. Early in the process, the turntable is shown to start spinning by accelerating to a dispense speed, shown as plateau 61. The dispense spin speed can be any speed that will allow dispensing of the photoresist solution onto the substrate to form a film or layer over the entire substrate surface in an efficient amount of time. The turntable speed will depend on factors such as the size of the wafer, but a typical dispense spin speed for a 200 mm diameter wafer might be in the range from about 1000 to about 2000 rpm, for example about 1500 rpm.

The photoresist solution can be applied in any fashion that will allow casting to a uniform film. The amount of photoresist solution applied can be important in providing a uniform photoresist film (at least a minimum amount is needed to form a film over the entire area of the substrate). As such, the dispense can preferably be monitored in terms of the amount of material dispensed, by considering the actual amount of photoresist solution dispensed or the timing of the dispense. According to a preferred embodiment of the invention, the pressure of the photoresist solution in the dispense line can be monitored by a pressure sensor at the photoresist solution dispense line, in a position to detect a point that represents an end of the photoresist dispense. The end point of dispense, according to an embodiment of the invention, can be selected to be a point selected from FIG. 10, that corresponds to an end of dispense, e.g., an arbitrary point in pressure profile II or III of line B of FIG. 10, such as a point at which pressure in a dispense line returns to a Zero Reference. In FIG. 4, this point is indicated to be point 57. This method provides a precise method for identifying a repeatable moment in the dispensing process at which the photoresist solution is considered done being dispensed. This point can be used in a preferred process control system, e.g., to act as a trigger event upon which subsequent process steps are timed and performed.

Preferably (and as shown), but not necessarily in all embodiments of the invention, dispensing of the photoresist solution onto the substrate surface can occur with spinning of the substrate. In a preferred embodiment, photoresist solution can be dispensed onto the substrate while the substrate rotates at a dispense speed, in an amount sufficient to cause the entire area of the substrate surface to be wetted, i.e., in an amount that is at least enough to create a complete layer of photoresist solution over the entire area of the substrate. When sufficient photoresist solution has been applied to cover the surface of the substrate, this is a good time to stop the dispense of photoresist solution and accelerate to casting or final spin speed. (As described below, it can be preferred to first move the dispense arm out of a position above the substrate.)

The dispense step typically involves movement of a dispense arm before, during, and after actual dispense of photoresist solution. Specifically, during dispense portion -A-, the dispense arm is shown to move from a non-dispensing position to a dispensing position, shown as plateau 64. While the turntable spins at the dispense speed, and while the arm is in the dispensing position, photoresist solution is applied to the substrate, shown as plateau 69, ending at point 59. Point 59 can be considered to be the point at which the dispensing apparatus, e.g., dispense pump or dispenser, considers that an “end of dispense” (EOD signal) has occurred. A short time after that, the dispense actually does stop, as is illustrated in greater detail in FIG. 10 (e.g., a measured end of dispense can be considered to be a selected point of profile II or III, such as when the profile crosses the Zero Reference or any other arbitrary value measured by the pressure sensor). FIG. 4 illustrates the actual end of dispense as measured by the pressure sensor, as point 57, which corresponds to the point of FIG. 10 that is selected as corresponding to the end of the dispense for purposes of process control, e.g., the point at which the reading from the pressure sensor crosses the Zero Pressure Reference.

The end of the photoresist solution dispense can be an important moment with respect to process control, because it precedes a number of time-sensitive commands or process steps. Moreover, the moment of the end of dispense can vary because of reasons including the timing of earlier steps or process imperfections relating to dispense, such as pump and fluid behavior or filter clogging. Thus, while not necessarily so, and while other trigger events can also be used, the end of dispense of the photoresist solution can be a particularly convenient trigger event for controlling a photoresist spin-coating process.

At the end of dispense of the photoresist solution, the dispense arm moves out of the way and back to a non-dispensing position. FIG. 4 shows how this can be preferably accomplished, to allow the turntable to accelerate after the end of photoresist solution dispense to a final spin speed in the shortest amount of time (to expedite acceleration to casting speed). The arm is first moved sufficiently out of the way to accelerate the substrate to casting spin speed, e.g., to the edge of the substrate. The substrate is then accelerated to the final spin speed as soon as possible. (Line segment 65 shows acceleration of the spin motor from a dispense speed to a casting speed.) After acceleration and/or achieving final spin speed, the arm is moved into the fully non-dispensing position (line segment 67). (This movement of the dispense arm can be a time-sensitive step.)

Upon application of a desired amount of photoresist solution onto the substrate, the substrate is accelerated to a final or cast spin speed (see section -B-, including line segment 65). The timing of this step has significant effect on the final thickness of a spin-coated photoresist, and as noted, the beginning and end of acceleration of the turntable from the dispense speed are both preferably executed with interrupted control methods. The final speed and the duration of the casting speed segment should be designed to result in a desired film thickness. Generally, thicknesses of up to about 50 microns are desired, down to thicknesses of less than 5, 1, or 0.5 micron. The coating should preferably be coated to very narrow tolerances with respect to thickness and thickness uniformity, and with the process control described herein, uniformities of less than 15 Angstroms (3 sigma), preferably less than 5 Angstroms (3 sigma), or even better, can be attained both intra- and inter-wafer. These values are measured of the coating after soft bake and prior to masking and exposure of the photoresist.

Optionally, multiple spin-coating systems or bowls can be used in a cluster of processing equipment, including within the cluster other equipment such as spin-coating systems for applying developer solution, hot plates, and chill plates, etc. Each of the multiple bowls for spin-coating photoresist will exhibit its own characteristics, possibly including variations in coating thickness (on average) relative to the other bowls of the cluster, with all parameters and conditions being set and controlled identically. These thickness variations can be compensated for by lengthening or shortening the amount of time the substrate is spun in the final or cast spin step (plateau 60 in FIG. 4). Preferably, this can be done by starting the acceleration to cast spin speed either slightly earlier or slightly later (point 73 of FIG. 4 can be executed slightly earlier or slightly later).

After casting portion -B- is the edge bead removal and backside wash portion, identified as portion -C-. This includes rotation at a speed similar to the dispense speed, movement of the dispense arm as shown, to the edge of the substrate, and dispensing an edge bead removal solvent, as designated by line 58, from the dispenser onto the substrate's edge to remove photoresist material that has beaded up on the edge. While this occurs, the backside of the substrate is rinsed, e.g., with streams of edge bead removal solvent.

The substrate can be processed further, typically by exposing the photoresist layer to radiation through a mask, and with one or more other steps such as bake and/or chill steps.

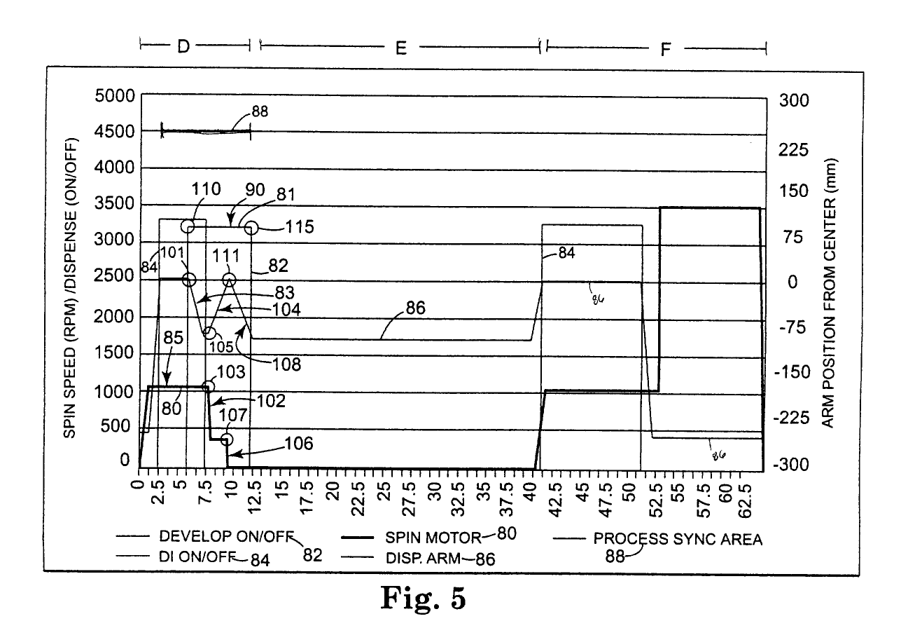

A developer solution can be applied to the substrate over the exposed photoresist. Some general steps of applying a developer solution using spin-coating are illustrated in FIG. 5. These include a first portion wherein developer is applied to the surface of the substrate (“dispense” or “puddle formation” portion -D-). This is followed by a “puddle time” portion -E-, which allows the developer solution to react with and dissolve regions of the photoresist. The puddle time portion is followed by a rinse and spin dry portion -F-. During the rinse portion, additional process solution such as deionized water or developer solution may be dispensed onto the substrate to carry away the dissolved photoresist. Final drying can take place as desired, e.g., using elevated temperature, centrifugal energy, and/or reduced pressure.

According to the invention, a process of spin-coating a developer solution can be accomplished using apparatuses and methods that incorporate a pressure sensor to monitor the pressure of a developer solution or another process solution, during dispense, especially to detect the beginning or end of a dispense, e.g., the beginning of the developer solution dispense. Also preferably, the process can include at least a portion that is controlled using interrupt timing methods. A preferred portion for using interrupted control is portion -D-, relating to developer solution dispense.

The developer solution can be applied to the surface of a substrate in any manner that will effectively allow reaction with and removal of regions of the developed photoresist. A developer solution is typically applied to a photoresist layer in a manner such that the developer solution will evenly interact with and develop the layer of photoresist material, causing either the exposed or unexposed area of photoresist to dissolve, and allowing that portion to be washed away to leave behind a positive or negative pattern of the mask. The developer solution can preferably be applied to minimize the amount of mechanical impingement, or to make such impingement uniform over a substrate's surface, and also to provide as much uniformity as possible with respect to the amount of time that the photoresist surface is in contact with developer solution. Ideally, the developer will be applied to and contact all areas of the photoresist surface equally, for an equal amount of time, resulting in uniform developing of the photoresist. In spin-coating methods, this can be approximated by applying the developer solution in a circular or spiral pattern, e.g., by rotating the substrate and either using movement of the dispenser to form a spiral pattern, or using manifold points of dispense to form a number of circular patterns.

The degree of uniformity and consistency of the application of the developer solution over a (preferably) uniform coated photoresist can be measured by considering the uniformity with which the photoresist was developed, which can be measured, e.g., by considering the size (typically width) and uniformity of the features remaining after development and removal of portions of the photoresist. Measurement of this value can be taken after baking the substrate following developing and removal of regions of photoresist. Typically, this means considering line width of remaining features using a test called line width repeatability. By use of methods of the present invention, photoresist layers can be produced having line width repeatability of 9 nanometers (3 sigma) intra-wafer, and 6 nanometers (3 sigma) inter-wafer.

Generally, an amount of developer solution in the range from about 30 to 50 milliliters, preferably about 40 milliliters (for a substrate having a diameter of 200 millimeters) can be applied in a generally even and uniform layer over an entire surface of a layer of photoresist. Of course more or less may be used if desired for any reason. Optionally, another process solution, e.g., deionized water, can be dispensed onto the substrate prior to or in combination with the developer solution, to wet or pre-wet the substrate and to improve interaction between the coated photoresist and the developer solution.

FIG. 5 illustrates exemplary steps used in spin-coating a developer solution to a substrate surface, over an exposed layer of photoresist. (The photoresist would have preferably but not necessarily been applied using spin-coating.) Line 80 represents the speed of the spin motor. Light line 82 represents dispensing of developer solution. Line 84 represents dispensing of deionized water for rinsing. Line 86 represents the position of the dispense arm. And line 88 identifies a time-sensitive portion for the developer dispense process.

Referring to FIG. 5, the turntable spin speed is initially accelerated to a first speed, plateau 85, for dispensing developer solution. The dispense arm moves into a dispensing position at the center of the substrate and begins pre-wetting the substrate surface by dispensing deionized water, as shown by line 84. Dispense of developer solution begins at point 110 and occurs through plateau 90, and the dispense arm moves from the center of the substrate to the edge of the substrate (line segment 83). Dispensing of developer solution continues as the dispense arm pauses slightly at the edge of the substrate, at which time the turntable speed is reduced (line segment 102) (Note: The deionized water has been turned off by point 103.) The dispense arm then returns (line 104) to the center of the substrate (point 111) where turntable speed is reduced to zero (line segment 106) and then back to the substrate edge (line segment 108). Around this point, dispensing of developer solution ends (point 115). After the developer dispense, the substrate has a puddle of developer solution on it, and it stands through -E-. At the bottom of the puddle, the developer solution is selectively removing the photoresist coating from the film. At about 40+ seconds (start of -F-), the dispense arm moves to the center of the substrate and the turntable starts rotating. This throws off much of the developer solution. Shortly afterwards, the deionized water dispense is started and the substrate is spun faster. After adequate rinsing, the dispense arm moves off the substrate to the “Home Position” and the deionized water dispense is turned off. The substrate is then spun faster to dry off the substrate.

The start of developer dispense, point 110, can be an especially important moment in the process, because it is the start of the movements of the dispense arm, as described. Because of this, the start of dispense can be a particularly good trigger event for controlling timing of subsequent process events of a process of spin-coating a developer solution. According to the invention, therefore, the start of dispense of the developer solution can be identified using a pressure sensor. According to the invention, subsequent process events can be controlled based on the timing of the beginning of dispense, at point 110. Alternatively, based on the process illustrated in FIG. 5 or based on a different recipe or program for spin-coating developer solution onto a photoresist, a trigger event can also or alternatively be the start (or end) of dispense of a different process solution, e.g., deionized water, also dispensed during spin-coating the developer solution.

Using parallel process control, as opposed to strictly “round-robin,” serial control, a spin-coating process as described according to the invention can be controlled using an interrupt process control system, wherein serial control of a spin-coating process is interrupted by an interrupt signal, whereupon the process control system executes a pre-programmed process command or initiates a series of commands (e.g., in the form of an interrupt service routine) and then returns to serial control. The interrupt signal can be external or internal (from the process control system, in the form of a software interrupt). For example, the interrupt signal may be a software signal programmed into the process control system to be sent at a programmed time or upon occurrence of an event detected within a software program. Or, the interrupt signal may be a hardware interrupt such as a discrete signal from a component of a spin-coating system such as a sensor, controller, pump, dispenser, turntable, timer, etc. A hardware interrupt is an interrupt signal from a piece of hardware, and is preferably a discrete signal sent directly to the CPU, e.g., through a hard-wired connection.

The process command executed upon interruption of serial control can be generally any command that is a part of the spin-coat process. The method is especially useful for controlling the timing of time-sensitive commands. Time-sensitive commands are process commands that relate to a process step whose timing, e.g., at magnitudes in the range of milliseconds, can have a measurable effect on uniformity of a coated or applied processing material, specifically including commands that can affect either a photoresist thickness or line width repeatability. Examples of time-sensitive commands include movements of hardware components such as turntable movement (e.g., acceleration or deceleration), dispenser movement, and starting or ending of process solution dispensing from a dispenser. Timing of turntable movements can be particularly important to spin-coated film thickness, because speed, duration, and acceleration of the turntable to distribute a process solution (especially a photoresist solution) into a uniform thin film, will affect the end thickness and uniformity of the film that is produced. Timing of dispense arm movements with turntable movements and process solution dispense can be particularly important for developer dispense and will affect the size (typically width) and uniformity of the features remaining after development.

The interrupt signal can be sent to the CPU upon occurrence of a “process event.” The terms “process event” and “trigger event” are used to refer to events that occur in a spin-coating process, and that can be detected or recognized by the CPU in the process control system. A trigger event can preferably be related to an event that either shortly precedes a time-sensitive command, or an event that either shortly precedes or initiates a time-sensitive period (a portion of a process that includes one or more time-sensitive commands).

A preferred trigger event can be different for different types of processes, such as for a photoresist spin-coating process versus a developer solution application process. Because a photoresist spin-coating process includes time-sensitive commands after the end of the photoresist solution dispense, and because the end of the photoresist solution dispense for a given amount of a solution can vary, a convenient trigger event for a photoresist spin-coating process can be the end of the photoresist solution dispense, particularly as measured using a pressure sensor, as described herein. For developer solution spin-coating processes, some of the steps immediately following the start of developer solution dispense can be time-sensitive, so a convenient trigger event for developer solution application can be the start of developer solution dispense, also preferably as measured using a pressure sensor as described herein.

Upon receiving the interrupt signal, the CPU can execute one or more process commands according to a set of instructions pre-programmed to be performed upon receipt of the interrupt signal, e.g., by executing an interrupt service routine (“ISR”). The interrupt service routine may include instruction to execute only a single process command, or may include instructions to execute multiple process commands. In either case, either a single process command or one or more of multiple process commands may be delayed from the trigger event or may be executed upon the occurrence of the trigger event. The duration of the one or more delays can be measured by one or more timers in the process control system. At the end of each duration, the ISR will send out another interrupt signal that will be recognized by the process control system, and the process control system will immediately execute the delayed process command according to that later interrupt signal.

In one embodiment, a trigger event causes the process control system to execute an interrupt service routine that contains multiple timers to measure multiple durations of delay. The interrupt service routine starts one timer running for each delay, and upon reaching the end of each delay, the interrupt service routine sends another interrupt signal to the processor, which recognizes the interrupt signal and interrupts serial process control to execute a (pre-programmed) process command. After the process command is executed, the process control system returns to serial control until it is again interrupted by another interrupt signal sent when another of the timers reaches the end of its measured duration or upon receiving another interrupt signal such as a hardware interrupt. While it is often convenient to measure each duration from the same starting point, e.g., the same trigger event or interrupt signal, it is not required that different durations of an ISR are all measured from the same start. The interruption may take the CPU away from the general, serial, control mode for a period of about 10 to 100 milliseconds, after which the process control system returns to serial control until it receives another interrupt signal.

The process control system can be programmed or pre-programmed (e.g., by pre-scanning or pre-programming a program e.g., including an ISR, into the process control system before running the spin-coating system) to recognize one or more different interrupt signals. The pre-scanning can also include programming an ISR that corresponds to each of the different interrupt signals. When each interrupt signal is received, the process control system will respond by executing the ISR that corresponds to the particular interrupt signal received.

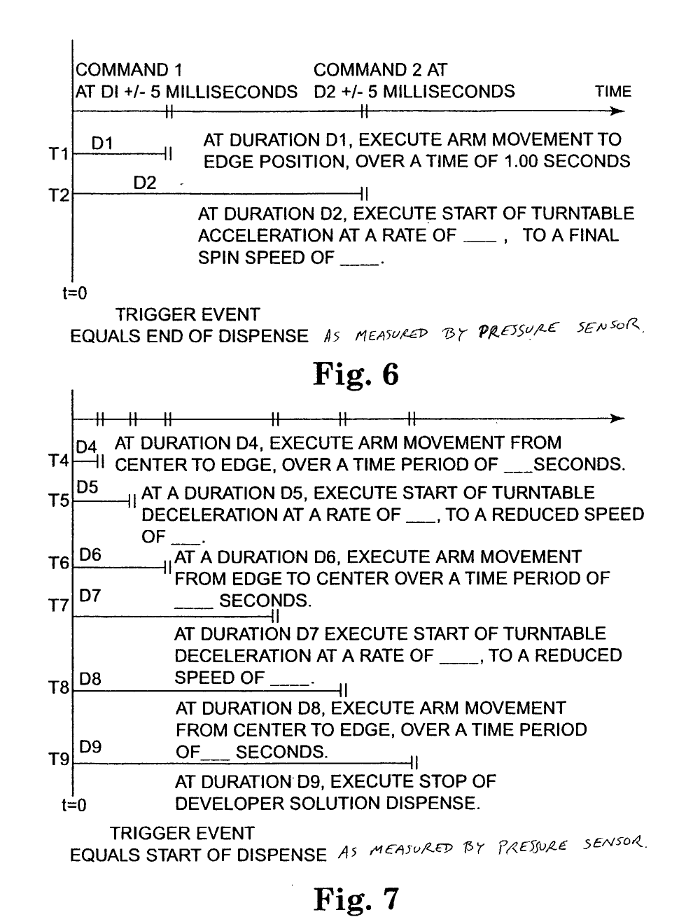

FIG. 6 illustrates a portion of the spin-coat process of FIG. 4, controlled using interrupt timing control and parallel timers that time process durations from a single trigger event. FIG. 6 shows a trigger event occurring during an exemplary photoresist solution spin-coating process. Preferably a trigger event can be chosen as the end of dispense of the photoresist solution, and identified using a pressure sensor as described, e.g., in the photoresist solution dispense line. When an end of dispense is detected, a discrete signal is sent to the CPU as a trigger event. The trigger event is represented in FIG. 6 as the vertical line also representing t=0. One or more timers (T1 and T2 in the figure) begin running, each for a preset duration from time zero and the trigger event.

According to this embodiment of the invention, one process command is executed at the end of each duration. The earliest process command is executed after the shortest duration (duration D1 in FIG. 6). Upon reaching the end of the duration, the interrupt service routine sends another interrupt signal (signaling the end of duration D1) to the central processing unit. The CPU will act as it is programmed to act upon receiving the signal relating to the end of duration D1, and will execute the appropriate process command. Here, for example, the process command can be movement of the dispense arm from above the center of the substrate to an edge (line segment 95 of FIG. 4). After the process command is executed, serial control is resumed. Upon reaching the end of duration D2, another interrupt signal is sent out, interrupting serial control to execute another process command. In the case of this example, the second process command can be start of acceleration of the turntable to cast speed. (Point 73, FIG. 4).

FIG. 7 illustrates a portion of the spin-coat process of FIG. 5, controlled using interrupt timing control and parallel timers that time process durations from a single trigger event. FIG. 7 shows events following a trigger event occurring during the spin-coating application of a developer solution. As illustrated in this embodiment, the trigger event can be chosen as the start of dispense of the developer solution (approximately point 110 of FIG. 5), as identified using a pressure sensor, e.g., in the developer solution dispense line. This trigger event can be chosen so that time-sensitive commands that closely follow the start of dispense can be timed from the start of developer solution dispense.

When the start of dispense is detected, a discrete signal is sent to the CPU (e.g., the supply system 32 sends a discrete signal to the control system 36 (see FIG. 2)). The trigger event is represented in FIG. 7 as the vertical line also representing t=0. Timers (T4, T5, T6, T7, T8, and T9 in the figure) begin running, each for a preset duration from time zero.

At the end of duration D4 (point 101 of FIG. 5), the interrupt service routine sends a signal to the CPU to interrupt serial processing and execute a command that begins moving the dispense arm from a position over the center of the substrate to a position over its edge (line segment 83 of FIG. 5).

At the end of duration D5 (point 103 of FIG. 5), the interrupt service routine sends a signal to the CPU to interrupt serial processing and execute a command that begins decelerating the turntable at a given rate, to a reduced speed (line segment 102 of FIG. 5).

At the end of duration D6 (point 105 of FIG. 5), the interrupt service routine sends a signal to the CPU to interrupt serial processing and execute a command that begins moving the dispense arm from a position over the edge of the substrate to a position over its center (line segment 104 of FIG. 5).

At the end of duration D7 (point 107 of FIG. 5), the interrupt service routine sends a signal to the CPU to interrupt serial processing and execute a command that begins decelerating the turntable at a given rate, to a reduced speed (line segment 106 of FIG. 5).

At the end of duration D8 (point 111 of FIG. 5), the interrupt service routine sends a signal to the CPU to interrupt serial processing and execute a command that begins moving the dispense arm from a position over the center of the substrate to a position over its edge (line segment 108 of FIG. 5).

At the end of duration D9 (point 115 of FIG. 5), the interrupt service routine sends a signal to the CPU to interrupt serial processing and execute a command stopping dispense of the developer solution.

Through all of the steps of the spin-coating process, a process control system acts according to its pre-programmed instructions, e.g., software instructions. This includes instructions relating to serial control, software interrupt signals, interrupt service routines, etc. The control process system can be programmed to execute instructions based on priorities, which allows the system to be interrupted while executing a relatively lower priority command (e.g., a serial control subroutine) to execute a command of a higher priority (e.g., a command from an interrupt service routine). The process control system can be programmed or pre-programmed to recognize signals such as interrupt signals, and to respond by executing the appropriate command, such as by initiating an ISR.

Preferred, interrupt-driven, parallel process control systems, in combination with the inventive use of a pressure sensor to monitor dispensing of process solutions, can reduce or eliminate timing variabilities that exist by using other process control methods and other methods of sensing a beginning or an end of a process solution dispense. Use of a pressure sensor to detect a beginning or end of dispense provides a method of directly identifying a repeatable point of dispense upon which the timing of later process steps can be based. This provides improved precision over indirect measurement of a beginning or end of dispense, based on other process events such as a signal from a pump or a dispenser, for example.

Additional improvements in an overall spin-coating process occur based on the use of interrupt-driven, parallel timing controls, e.g., to control the timing of later process events based on a beginning or end of dispense measured using a pressure sensor. Interrupt-driven, parallel timing allows for process commands to be executed and delay durations to be measured to within the accuracy of the timing device measuring the duration, which for modern computers can be to within about 5 milliseconds, or even to an accuracy within 1 millisecond or less. Furthermore, process commands can be measured independently, i.e., in parallel, so variabilities present in the timing of execution of earlier commands will not propagate and accumulate into the timing of subsequent processing commands.

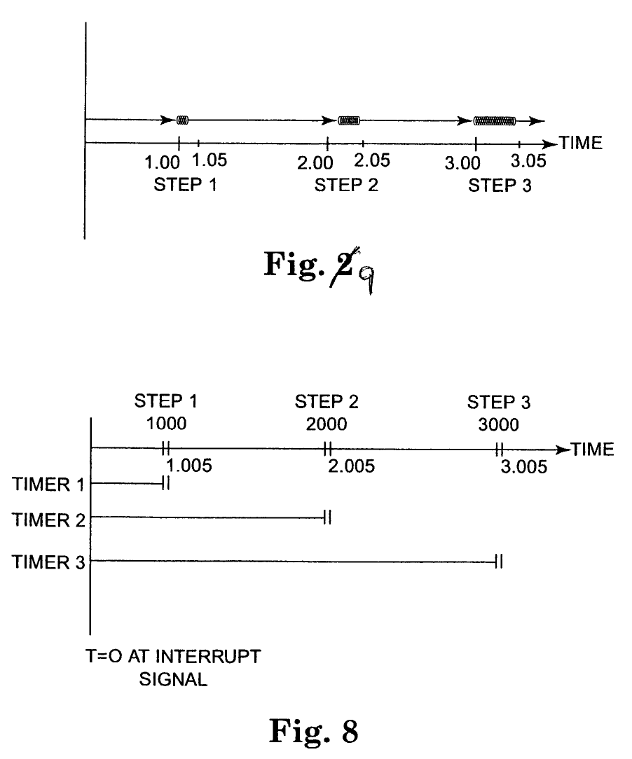

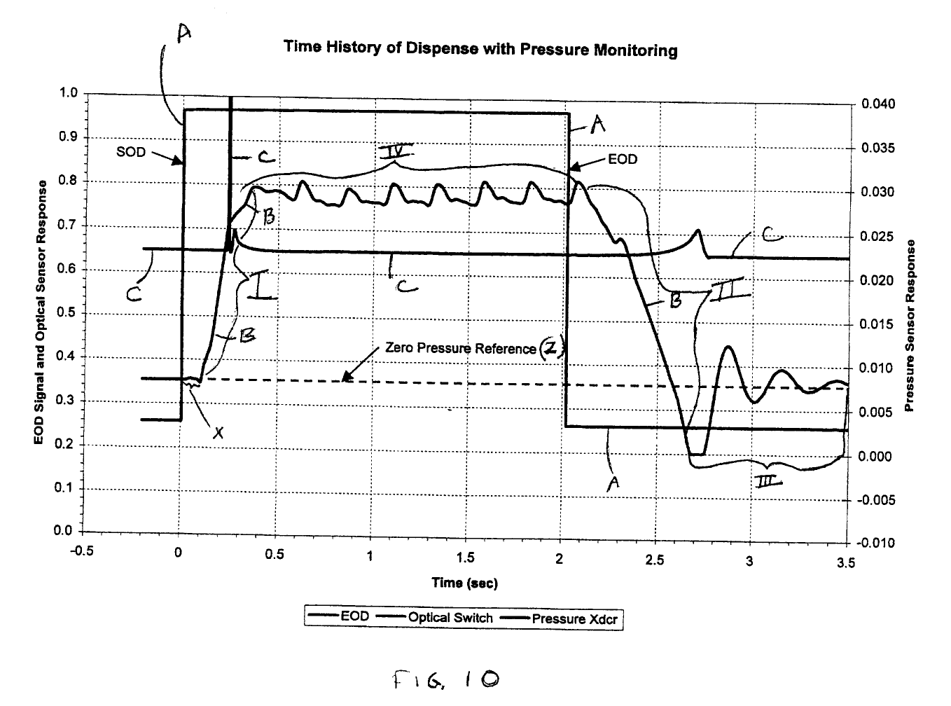

FIG. 8 illustrates variations present in one or multiple steps controlled with interrupted, preferably parallel timing. FIG. 8 shows a first step being executed from an interrupt at a time in the range from 1.000 to 1.005 seconds. A second step, timed with a parallel timer, is executed at a time in the range from 2.000 to 2.005 seconds, and a third step executes at a time from 3.000 to 3.005 seconds. Referencing FIG. 9 shows that the variabilities associated with parallel control compare favorably to the variabilities associated with serial control. The use of a pressure sensor to measure the beginning or end of a dispense step can provide even more precision to the method.

1. A spin-coating system comprising a supply of process solution in fluid communication with a dispenser through a dispense line, and a pressure sensor that measures pressure of the process solution in the dispense line at a time related to a step of dispensing the process solution, to control timing of a subsequent spin-coating process step.

2. The system of claim 1 wherein the pressure sensor comprises a pressure transducer.

3. The system of claim 1 comprising a dispense valve between the supply of process solution and the dispenser, and the pressure sensor is between the dispense valve and the dispenser.

4. The system of claim 1 wherein the pressure sensor detects a beginning or end of process solution being dispensed from the dispenser.

5. The system of claim 1 further comprising a control system for controlling a spin-coating process, wherein the pressure sensor detects a beginning or end of process solution dispense from the dispenser, and the pressure sensor sends a signal to the control system at a detected beginning or at a detected end of process solution dispense.

6. The system of claim 5 wherein the process solution is a photoresist solution and the pressure sensor signals the control system at a detected end of photoresist solution dispense.

7. The system of claim 5 wherein the process solution is a developer solution and the control pressure sensor signals the control system at a detected start of developer solution dispense.

8. The system of claim 1 wherein the process solution is selected from the group consisting of a photoresist, a developer, a solvent, and deionized water.

9. A spin-coating system comprising:
a turntable to support and rotate a substrate;
a dispenser moveable between a dispensing position and a non-dispensing position;
a supply of process solution in fluid communication with the dispenser through a dispense line;
a pressure sensor that measures pressure of the process solution;
a process control system that controls application of the process solution to the substrate, the process control system being programmed to interrupt serial control to execute a process command.

10. The system of claim 9 wherein
the system comprises a dispense valve between the supply of process solution and the dispenser,
the pressure sensor measures pressure of the process solution in the disperse line, and
the pressure sensor is between the dispense valve and the dispenser.

11. The system of claim 9 wherein the process solution is chosen from the group consisting of a photoresist solution and a developer solution.

12. The system of claim 9 wherein the pressure sensor sends a signal to the control system at the beginning or the end of dispense of the process solution, and the control system interrupts control of the process.

13. The system of claim 12 wherein the process solution is a photoresist solution and the pressure sensor sends a signal to the control system at an end of photoresist solution dispense.

14. The system of claim 12 wherein the process solution is a developer solution and the pressure sensor sends a signal to the control system at the start of developer solution dispense.

15. The system of claim 9 wherein the process solution is selected from the group consisting of a photoresist, a developer, deionized water, and a solvent.

16. A method of spin-coating a process solution onto a substrate, the method comprising
providing a spin-coating system comprising a supply of process solution in fluid communication with a dispenser,
dispensing the process solution through the dispenser onto the substrate, and
measuring pressure of the process solution to detect a beginning or an end of dispense of the process solution by the dispenser.

17. The method of claim 16 wherein the spin-coating system comprises a supply of process solution in fluid communication with a dispenser through a dispense line, and a pressure sensor measures the pressure of the process solution in the dispense line.

18. The method of claim 16 wherein the spin-coating system comprises a dispense line between the supply of process solution and the dispenser, a valve in the dispense line, and a pressure sensor to measure pressure of the process solution in the dispense line between the valve and the dispenser.

19. The method of claim 16 wherein the method comprises initiating a later process step based on the beginning or end of process solution dispense measured using the pressure sensor.

20. A method of spin-coating a photoresist onto a semiconductor wafer, the method comprising the steps of
spin-coating photoresist solution onto a surface of the semiconductor wafer, and
spin-coating developer solution onto the photoresist material,
wherein the method includes using a pressure sensor to measure one or more of the beginning or end of dispense of the photoresist solution or the beginning or end of dispense of the developer solution.

21. The method of claim 20 comprising using a pressure sensor to measure the beginning of developer solution dispense, and using a pressure sensor to measure the end of photoresist solution dispense.

22. A method of controlling a spin-coating process using a spin-coating system comprising a supply of process solution in fluid communication with a dispenser through a dispense line and a pressure sensor that measures pressure of the process solution in the dispense line, the method comprising the use of a process control system programmed with an interrupt service routine,
wherein upon a trigger event relating to a signal related to dispense of process solution measured using the pressure sensor, a hardware interrupt is sent to the process control system,
upon receiving the hardware interrupt, the process control system executes an interrupt service routine.

23. The method of claim 22 wherein the interrupt service routine includes
setting two or more timers to run in parallel for durations, and
sending a software interrupt at the end of each timer duration to interrupt the process control system and execute a process command.

24. A spin-coating system comprising a supply of process solution in fluid communication with a dispenser through a dispense line and a pressure sensor that measures pressure of the process solution to detect a malfunction in the apparatus.

25. The system of claim 24 wherein the malfunction is an equipment malfunction.

26. The system of claim 24 wherein the system detects a malfunction by measuring pressure of process solution in the dispense line during dispense of the process solution.

27. The system of claim 26 wherein the process solution is selected from the group consisting of photoresist, developer, solvent, deionized water, and cleaner.

28. A method of detecting a malfunction in a spin-coating apparatus, the method comprising measuring a pressure of a process fluid.

29. The method of claim 28 wherein the pressure is measured in a dispense line during a dispense step.
